(19) United States
(12) Patent Application Publication
(10) Pub. No.: US 2019/0393244 A1
(43) Pub. Date: Dec. 26, 2019

(54) ARRAY SUBSTRATE AND MANUFACTURING METHOD THEREOF, DISPLAY PANEL AND DRIVING METHOD THEREOF, AND DISPLAY DEVICE

(71) Applicants: BOE Technology Group Co., Ltd., Beijing (CN); Hefei BOE Optoelectronics Technology Co., Ltd., Hefei, (CN)

(72) Inventors: Wenjian Wang, Beijing (CN); Jun Hong, Beijing (CN); Changjun Zhang, Beijing (CN); Liangliang Zheng, Beijing (CN)

(21) Appl. No.: 15/767,321

(22) PCT Filed: Oct. 24, 2017
(86) PCT No.: PCT/CN2017/107501

§ 371 Date: Apr. 10, 2018

(30) Foreign Application Priority Data
Apr. 5, 2017 (CN) 201710217527.3

(51) Int. Cl. H01L 27/12; H01L 21/02; H01L 29/66; H01L 29/786; G02F 1/1362; G02F 1/1368; G09G 3/36

(52) U.S. Cl. CPC H01L 27/124; G09G 2300/0465; H01L 27/127; H01L 21/02532; H01L 29/66757; H01L 29/78666; H01L 21/02592; G02F 1/136286; G02F 1/1368; H01L 29/66765; H01L 29/78669; G09G 3/3648; G09G 3/3696; G02F 2001/136295; G02F 2202/103; G02F 2001/13685; H01L 27/1222

(57) ABSTRACT

An array substrate and a manufacturing method thereof, a display panel and a driving method thereof, and a display device are provided in the present disclosure, in the field of displays. The array substrate includes a plurality of gate lines, a plurality of data lines, and a plurality of pixel units defined by the gate lines and the data lines in cross arrangement. The plurality of pixel units are arranged in an array. Each of the pixel units includes a thin film transistor. Each row of pixel units are connected to one corresponding gate line. Each row of pixel units comprise a plurality of pixel unit groups. Each pixel unit group comprises two pixel units of adjacent columns that are connected to one data line. Thin film transistors of the two pixel units in the pixel unit group are transistors of different types. When the array substrate reduces the number of the date lines by a half, there is no need to design two gate lines for one row of pixel units. Thus the number of the gate lines is reduced, and an aperture opening ratio of the TFT-LCD increases.

This application claims priority to Chinese Patent Application No. 201710217527.3, filed with the State Intellectual Property Office on Apr. 5, 2017 and titled “ARRAY SUBSTRATE AND MANUFACTURING METHOD THEREOF, DISPLAY PANEL AND DISPLAY DEVICE,” the entire contents of which are incorporated herein by reference.

### TECHNICAL FIELD

The present disclosure relates to display technology, and more particularly to an array substrate and a manufacturing method thereof, a display panel and a driving method thereof and a display device.

### BACKGROUND

A thin film transistor-liquid crystal display displays an image through controlling light transmitting intensity, which is achieved through the change of the orientation of liquid crystal molecules caused by the change of an electric field intensity on a liquid crystal molecular layer clamped between an upper substrate and a lower substrate. A liquid crystal display panel is a main component of the TFT-LCD and generally comprises a backlight module, a polarizer, an array substrate, a color filter substrate and a liquid crystal molecular layer filled in a box formed by the array substrate and the color filter substrate. Lots of pixel units are arranged in an array on the array substrate. Each pixel unit comprises a TFT. Generally, the TFTs of each row of pixel units are connected to a transversely disposed gate line. The gate line is configured to turn on or turn off the TFTs connected to the gate line. The TFTs of each column of pixel units are connected to a longitudinally disposed data line. The data line is configured to write data signals into the pixel units when the TFTs connected to the data line are turned on. The data line drives through a source integrated circuit (IC), and each data line corresponds to one data signal output channel (channel for short in the following text) of the source IC.

### SUMMARY

The present disclosure provides an array substrate and a manufacturing method thereof, a display panel and a driving method thereof and a display device. The technical solutions are as follows.

In a first aspect, there is provided an array substrate in the present disclosure. The array substrate includes: a plurality of gate lines, a plurality of data lines, and a plurality of pixel units defined by the gate lines and the data lines in cross arrangement, wherein the plurality of pixel units are arranged in an array. Each of the pixel units includes a thin film transistor. Each row of pixel units are connected to one corresponding gate line, and each row of pixel units comprise a plurality of pixel unit groups. Each pixel unit group comprises two pixel units of adjacent columns, and the two pixel units of adjacent columns are connected to one data line. Thin film transistors of the two pixel units in the pixel unit group are transistors of different types.

In an implementation of the present disclosure, in the thin film transistors of two pixel units in the pixel unit group, one thin film transistor is an N-type transistor, and the other thin film transistor is a P-type transistor.

In an implementation of the present disclosure, the N-type transistor comprises a gate electrode, a gate electrode insulating layer, a first active layer, a source-drain electrode and an insulating layer laminated in sequence; and the P-type transistor comprises a gate electrode, a gate electrode insulating layer, a second active layer, a source-drain electrode and an insulating layer laminated in sequence.

In an implementation of the present disclosure, the N-type transistor comprises a source-drain electrode, a first active layer, a gate electrode insulating layer, a gate electrode, and an insulating layer laminated in sequence; and the P-type transistor comprises a source-drain electrode, a second active layer, a gate electrode insulating layer, a gate electrode, and an insulating layer laminated in sequence.

In an implementation of the present disclosure, the N-type transistor comprises a first active layer, a gate electrode insulating layer, a gate electrode, a source-drain electrode insulating layer, a source-drain electrode, and an insulating layer laminated in sequence; and the P-type transistor comprises a second active layer, a gate electrode insulating layer, a gate electrode, a source-drain electrode insulating layer, a source-drain electrode, and an insulating layer laminated in sequence.

In an implementation of the present disclosure, the first active layer comprises an N-doped amorphous silicon n a-Si layer and a heavily N-doped amorphous silicon n+ a-Si layer; and the second active layer comprises a P-doped amorphous silicon p a-Si layer and a heavily P-doped amorphous silicon p+ a-Si layer.

In a second aspect, there is provided a method for manufacturing an array substrate in the present disclosure. This method may be used to manufacture the any of the array substrates in the first aspect. The method includes: forming gate lines, data lines, active layers and source-drain electrodes on a substrate, to form a plurality of first thin film transistors and a plurality of second thin film transistors. The active layers comprise a first active layer and a second active layer, the first active layer being an active layer of the first thin film transistors, and the second active layer being an active layer of the second thin film transistors. The gate lines and the data lines intersect with each other to define a plurality of pixel units. The plurality of pixel units are arranged in an array, and each pixel unit comprises a thin film transistor. Each row of pixel units are connected to one corresponding gate line, and each row of pixel units comprise a plurality of pixel unit groups. Each pixel unit group comprises two pixel units of adjacent columns, and the two pixel units of adjacent columns are connected to one data line. The first thin film transistor and the second thin film transistor are two thin film transistors corresponding to the two pixel units of adjacent columns in the pixel unit group, and the first thin film transistor and the second thin film transistor are transistors of different types.

In an implementation of the present disclosure, forming the gate lines, the data lines, the active layers and the source-drain electrodes on a substrate comprises: forming a gate electrode layer pattern on the substrate, wherein the gate electrode layer pattern comprises a plurality of gate lines and a plurality of gate electrodes; forming a gate electrode insulating layer on the gate electrode layer pattern; forming a first active layer and a second active layer on the gate electrode insulating layer; and forming a source-drain electrode layer pattern on the first active layer and the second active layer, the source-drain electrode layer pattern comprising a plurality of data lines and a plurality of source-drain electrodes.

In an implementation of the present disclosure, forming the gate lines, the data lines, the active layers and the source-drain electrodes on a substrate comprises: forming a source-drain electrode layer pattern on the substrate, the source-drain electrode pattern comprising a plurality of data lines and a plurality of source-drain electrodes; forming a first active layer and a second active layer on a source-drain metal pattern; forming a gate electrode insulating layer on the first active layer and the second active layer; and forming a gate electrode layer pattern on the gate electrode insulating layer, the gate electrode layer pattern comprising a plurality of gate lines and a plurality of gate electrodes.

In an implementation of the present disclosure, forming the gate lines, the data lines, the active layers and the source-drain electrodes on a substrate comprises: forming a first active layer and a second active layer on the substrate; forming a gate electrode insulating layer on the first active layer and the second active layer; forming a gate electrode layer pattern on the gate electrode insulating layer, the gate electrode layer pattern comprising a plurality of gate lines and a plurality of gate electrodes; forming a source-drain electrode insulating layer on the gate electrode layer pattern; and forming a source-drain electrode layer pattern on the source-drain electrode insulating layer, the source-drain electrode pattern comprising a plurality of data lines and a plurality of source-drain electrodes.

In an implementation of the present disclosure, forming the first active layer and the second active layer comprises: forming a first semiconductor layer, and forming the first active layer by a patterning process; and forming a second semiconductor layer, and forming the second active layer by a patterning process. The first active layer and the second active layer are located in regions of two pixel units of adjacent columns in the corresponding pixel unit group on the gate electrode insulating layer, respectively.

In an implementation of the present disclosure, forming the first semiconductor layer, and forming the first active layer by a patterning process comprises: forming a doped amorphous silicon layer; forming a heavily doped amorphous silicon layer; and processing the doped amorphous silicon layer and the heavily doped amorphous silicon layer by a patterning process to form the first active layer. Forming the second semiconductor layer, and forming the second active layer by a patterning process comprises: forming a doped amorphous silicon layer; forming a heavily doped amorphous silicon layer; and processing the doped amorphous silicon layer and the heavily doped amorphous silicon layer by a patterning process to form the second active layer.

In an implementation of the present disclosure, forming the first semiconductor layer, and forming the first active layer by a patterning process comprises: forming a heavily doped amorphous silicon layer; forming a doped amorphous silicon layer; and processing the heavily doped amorphous silicon layer and the doped amorphous silicon layer by a patterning process to form the first active layer. Forming the second semiconductor layer, and forming the second active layer by a patterning process comprises: forming a heavily doped amorphous silicon layer; forming a doped amorphous silicon layer; and processing the heavily doped amorphous silicon layer and the doped amorphous silicon layer by a patterning process to form the second active layer.

In an implementation of the present disclosure, the first semiconductor layer and the second semiconductor layer are formed in sequence, or the first semiconductor layer and the second semiconductor layer are formed alternately.

In an implementation of the present disclosure, forming a doped amorphous silicon layer comprises: depositing an undoped amorphous silicon layer, and doping the undoped amorphous silicon layer to obtain the doped amorphous silicon layer; or directly depositing a doped amorphous silicon layer.

In an implementation of the present disclosure, forming a heavily doped amorphous silicon layer comprises: depositing an undoped amorphous silicon layer, and doping the undoped amorphous silicon layer to obtain the heavily doped amorphous silicon layer; or directly depositing a heavily doped amorphous silicon layer.

In a third aspect, there is further provided a display panel in the present disclosure. The display panel includes any of the array substrates in the first aspect.

In a fourth aspect, there is further provided a display device in the present disclosure. The display device includes the display panel in the third aspect.

In a fifth aspect, there is further provided a method for driving a display panel in the present disclosure. This method may be used to drive the display panel in the third aspect. The method includes: outputting a gate electrode control signal to each gate line sequentially along a scan direction of the data line, wherein the gate electrode control signal comprises a first voltage signal and a second voltage signal, and the first voltage signal and the second voltage signal are configured to turn on two different types of transistors; outputting a first data signal to the plurality of data lines when the first voltage signal is output to any gate line, and outputting a second data signal to the plurality of data lines when the second voltage signal is output to any gate line, wherein the first data signal and the second data signal comprise a plurality of sub-signals output to the plurality of data lines, and each sub-signal is configured to drive the pixel units on one data line.

The technical solutions provided by the present disclosure may include the following advantageous benefits.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some of embodiments of the present disclosure, and a person of ordinary skill in the art may still derive other drawings from these accompanying drawings without creative efforts.

FIG. 1 is a structural schematic diagram of an array substrate provided in an embodiment of the present disclosure;

FIG. 2 is a flow chart of a method for manufacturing an array substrate provided in an embodiment of the present disclosure;

FIG. 3 to FIG. 24 are structural schematic diagrams of an array substrate during a manufacturing process provided in embodiments of the present disclosure;

FIG. 25 is a flow chart of a method for manufacturing another array substrate provided in an embodiment of the present disclosure;

FIG. 26 is a flow chart of a method for manufacturing another array substrate provided in an embodiment of the present disclosure; and

FIG. 27 is a flow chart of a method for driving a display panel provided in an embodiment of the present disclosure.

### DETAILED DESCRIPTION

The present disclosure will be described in further detail with reference to the enclosed drawings, to clearly present the objects, technique solutions, and advantages of the present disclosure.

As the resolution of the TF-LCD increases constantly, the column number of pixel units on an array substrate is increased, such that the number of data lines is more and more. Accordingly, due to the increased data lines, the channel number that can be provided by the source IC is also more and more, leading to a higher and higher cost of the source IC.

In order to reduce the cost of the source IC, a dual gate design may be adopted on the array substrate. In the dual gate design, one data line is connected to TFTs of adjacent two columns of pixel units, such that the number of the data lines is halved on the original basis. Therefore, the demand on the channel number of the source IC is reduced. Meanwhile, the TFTs of one row of pixel units are connected to two gate lines. The TFTs of two adjacent pixel units in the same row are connected to two gate lines respectively, such that one data line can write the data signal into two pixel units of adjacent rows in the same row in a time sharing manner. In the dual gate design, the number of the gate lines is doubled on the original basis, such that the area that can be transmitted by the light rays corresponding to each pixel unit is reduced, and finally, an aperture opening ratio of the TFT-LCD is caused to be low.

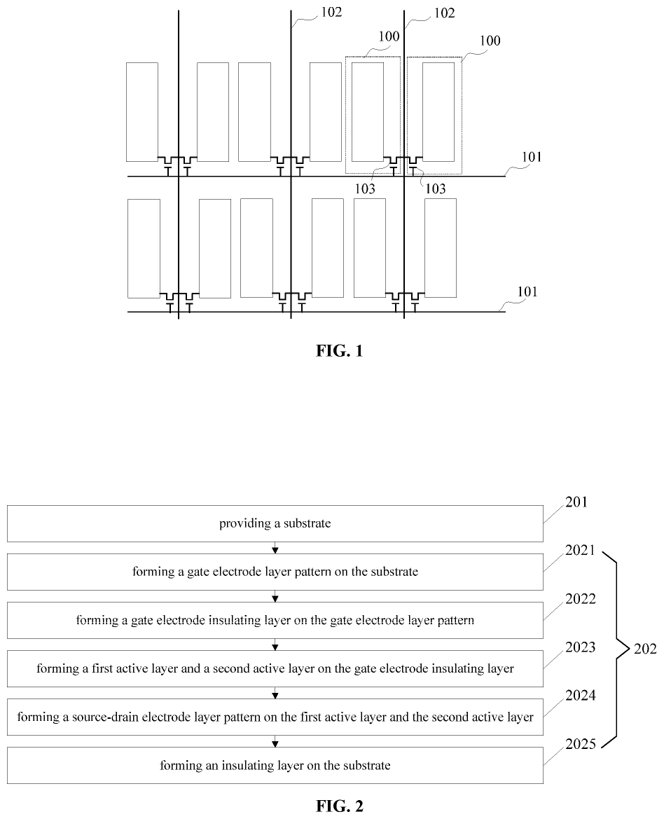

FIG. 1 is a structural schematic diagram of an array substrate provided in an embodiment of the present disclosure. Referring to FIG. 1, the array substrate includes a plurality of gate lines 101, a plurality of data lines 102, and a plurality of pixel units 100 defined by the gate lines 101 and the data lines 102 in cross arrangement. The plurality of pixel units are arranged in an array. Each pixel unit 100 includes a TFT 103. Each row of the pixel units 100 is connected to one corresponding gate line 101, and each row of pixel units includes a plurality of pixel unit groups. Each pixel unit group includes two pixel units 100 in adjacent columns and different pixel unit groups include different pixel units. The two pixel units 100 in the same pixel unit group are connected to the same data line 102 and have different types of TFTs.

In the present disclosure, two pixel units of adjacent columns in the same row are connected to one data line. The TFTs of the two pixel units in the same row connected to the same data line are transistors of different types. The pixel units of the same row are connected to one gate line. In this way, the TFTs of the two pixel units in the same row connected to the same data line may be controlled to be turned on and off in sequence by outputting different voltage signals through one gate line in a time sharing manner. It is ensured that the data signal is written into the two pixel units connected to two TFTs through one data line in a time sharing manner. That is, the control over the TFTs of one row of pixel units in the original dual gate design may be realized using one gate line. There is no need to provide two gate lines for one row of pixel units. Thus, the number of the gate lines is reduced, and the aperture opening ratio of the TFT-LCD increases.

Referring to FIG. 1, the gate lines 101 are disposed along a first direction, and the data lines 102 are disposed along a second direction. The first direction and the second direction intersect to define a plurality of pixel units 100. In the embodiment of the present disclosure, the first direction may the transverse direction and the second direction may be the vertical direction. The data lines and the gate lines are respectively disposed along the vertical direction and the transverse direction, which is convenient for manufacture.

In the embodiment of the present disclosure, in the TFTs of the two pixel units 101 in the pixel unit group, one TFT is an N-type transistor, and the other TFT is a P-type transistor. The TFTs of two pixel units of adjacent columns in the same row are respectively set to be the P-type transistor and the N-type transistor. In this way, the two TFTs may be controlled to be turned on and off in sequence by outputting a positive voltage signal and a negative voltage signal through one gate line in a time sharing manner. Therefore, no extra gate line is required when the number of the data lines (every two columns adopt one data line) is reduced by half, and thereby increasing the aperture opening ratio of the display panel.

The TFTs of the two pixel units of adjacent columns in the same row are respectively set to be a P-type transistor and an N-type transistor. That is, the TFTs 103 of two adjacent pixel units connected to the same gate line 101 are the P-type transistor and the N-type transistor. Then, the TFTs 103 of half of the pixel units 100 in one row are P-type transistors, and the other half are N-type transistors. The N-type transistors and the P-type transistors are disposed at intervals.

For one column of pixel units 100, the TFTs 103 of all the pixel units 100 may be P-type transistors or N-type transistors, for the convenience to manufacture the the array substrate. Or, the TFTs 103 of one column of pixel units 100 comprise both P-type transistors and N-type transistors. The P-type transistors and the N-type transistors are disposed at intervals, or the P-type transistors and the N-type transistors are irregularly distributed.

In the embodiment of the present disclosure, the TFTs of the two pixel units in the same row connected to the same data line may be controlled to be turned on and off by outputting different voltage signals through the gate line in a time sharing manner. Exemplarily, when the gate line outputs a positive voltage signal, the N-type transistor is turned on, and the P-type transistor is turned off. When a negative voltage signal is output, the P-type transistor is turned on, and the N-type transistor is turned off. The gate line outputs the positive voltage signal first and then outputs the negative voltage signal or outputs the negative voltage signal first and then outputs the positive voltage signal within the scan time of one row of pixel units.

In the embodiment of the present disclosure, the TFT 103 may be a bottom gate TFT or top gate TFT.

In the embodiment of the present disclosure, when the TFT 103 is a bottom gate TFT, the N-type transistor may include: a gate electrode, a gate electrode insulating layer, a first active layer, a source-drain electrode (a source electrode and drain electrode) and an insulating layer laminated in sequence, and the P-type transistor may include: a gate electrode, a gate electrode insulating layer, a second active layer, a source-drain electrode and an insulating layer laminated in sequence.

In the embodiment of the present disclosure, when the TFT 103 is a top gate TFT, the N-type transistor and the P-type transistor include two structures. For the first structure, the N-type transistor may include: a source-drain electrode, a first active layer, a gate electrode insulating layer, a gate electrode, and an insulating layer laminated in sequence, and the P-type transistor may include: a source-drain electrode, a second active layer, a gate electrode insulating layer, a gate electrode, and an insulating layer laminated in sequence. For the second structure, the N-type transistor may include: a first active layer, a gate electrode insulating layer, a gate electrode, a source-drain electrode insulating layer, a source-drain electrode and an insulating layer laminated in sequence, and the P-type transistor may include: a second active layer, a gate electrode insulating layer, a gate electrode, a source-drain electrode insulating layer, a source-drain electrode and an insulating layer laminated in sequence.

The first active layer comprises an N-doped amorphous silicon (n a-Si) layer and a heavily N-doped amorphous silicon (n+ a-Si) layer. The second active layer comprises a P-doped amorphous silicon (p a-Si) layer and a heavily P-doped amorphous silicon (p+ a-Si) layer. Exemplarily, when the TFT 103 is the bottom gate TFT or the top gate TFT of the second structure, the n a-Si layer and the n+ a-Si layer in the first active layer or the second active layer are laminated on the gate electrode insulating layer in sequence. When the TFT 103 is the top gate TFT of the first structure, the n+ a-Si layer and the n a-Si layer in the first active layer or the second active layer are laminated on the gate electrode insulating layer in sequence.

It should be noted that the pixel units 100, the gate lines 101 and the data lines 102 shown in FIG. 1 are formed on the substrate. The substrate may be a transparent substrate, for example, a glass substrate, a silicon substrate, a plastic substrate, etc., which is not limited in the present disclosure.

FIG. 2 is a flow chart of a method for manufacturing an array substrate provided in an embodiment of the present disclosure. The method may be adopted to manufacture the array substrate in FIG. 1. The TFT in the array substrate manufactured with the method shown in FIG. 2 is a bottom gate TFT. Referring to FIG. 2, the method includes following steps.

In step 201, a substrate is provided.

Exemplarily, step 201 may include: providing a substrate and cleaning the substrate. The substrate may be a transparent substrate, such as a glass substrate, a silicon substrate, a plastic substrate or the like.

In step 202: gate lines, data lines, active layers and source-drain electrodes are formed on the substrate to form a plurality of first TFTs and second TFTs. The active layers include first active layers and second active layers. The first active layer is the active layer of the first thin film transistor, and the second active layer is the active layer of the second thin film transistor. The manners for doping the first active layer and the second active layer are different. The gate lines and the data lines intersect to define a plurality of pixel units which are arranged in an array. Each row of the pixel units are connected to one gate line and include a plurality of pixel unit groups. Each pixel unit group includes two pixel units of adjacent columns that are connected to one data line. The first TFT and the second TFT correspond to the two pixel units of adjacent columns in the pixel unit group.

In the embodiment of the present disclosure, the first TFT and the second TFT are bottom gate TFTs. One of the first TFT and the second TFT is an N-type transistor and the other TFT is a P-type transistor.

Exemplarily, step 202 may include:

Step 2021: a gate electrode layer pattern is formed on the substrate and the gate electrode layer pattern includes a plurality of gate lines and a plurality of gate electrodes.

Specifically, step 2021 may comprise: forming a first conductive layer on the substrate, and processing the first conductive layer by a patterning process to form a gate electrode layer pattern.

The first conductive layer may be a metal layer made of, for example, Al, Cu, Mo, Cr, Ti, etc., or an alloy of the above metal. The first conductive layer may be made in a manner of sputtering, etc.

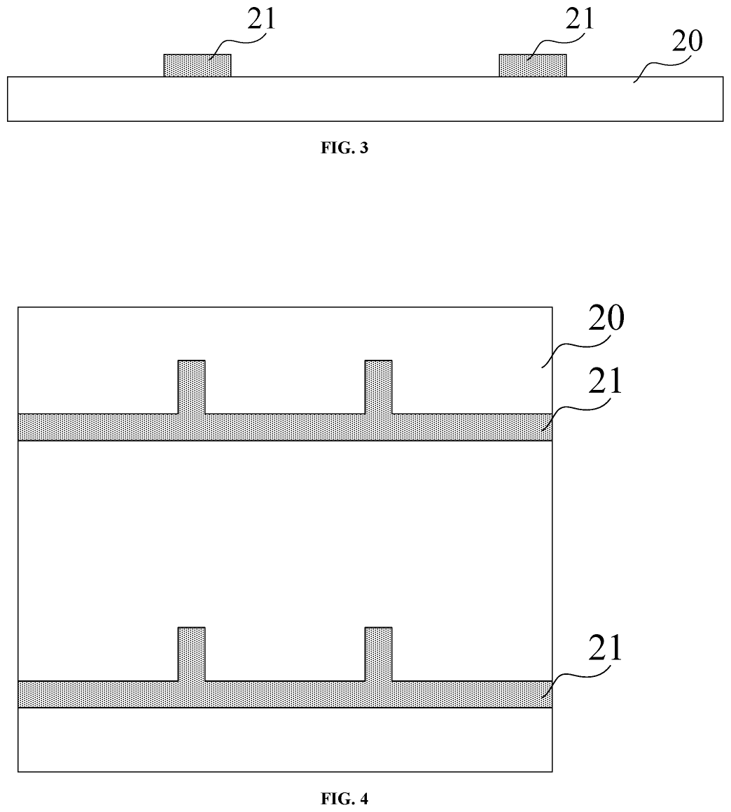

FIGS. 3 and 4 are structural schematic diagrams of an array substrate after the gate electrode layer pattern is formed in a manufacturing process. Referring to FIGS. 3 and 4, the first conductive layer is formed on the substrate 20 and is processed by the patterning process to form the gate electrode layer pattern 21. For example, the first conductive layer is formed on the substrate 20 in a sputtering manner, and then the gate electrode layer pattern 21 is obtained by an etching process. FIGS. 3 and 4 are merely schematic. In actual manufacturing, the number of the gate lines is the same as the number of the rows of the pixel units, and the number of the gate electrodes is the same as that of the pixel units.

Step 2022: a gate electrode insulating layer is formed on the gate electrode layer pattern.

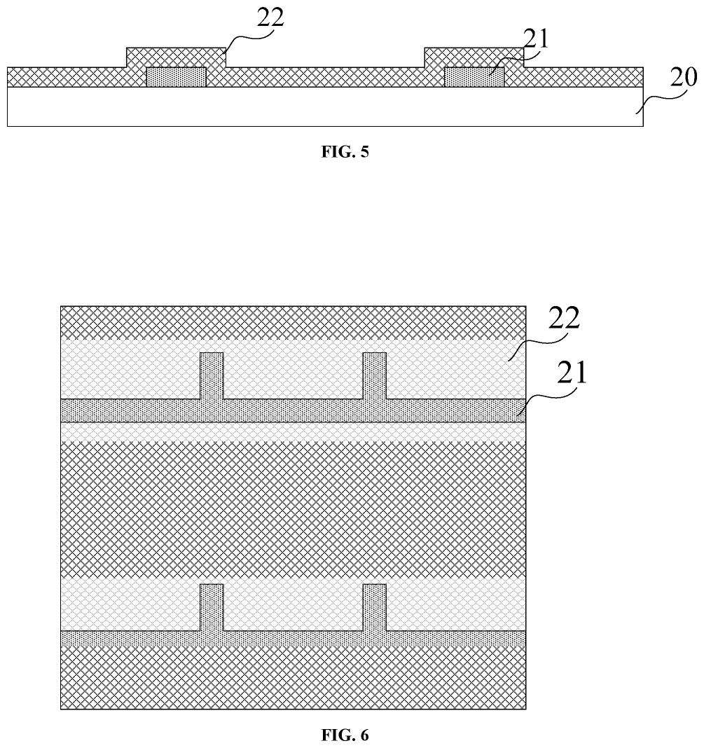

FIGS. 5 and 6 show structural schematic diagrams of the array substrate after the gate electrode insulating layer is formed in the manufacturing. Referring to FIGS. 5 and 6, after the gate electrode layer pattern is manufactured, a gate electrode insulating layer 22 is formed on the substrate 20 with the gate electrode layer pattern. For example, the gate electrode insulating layer 22 is deposited on the substrate 20. The gate electrode insulating layer 22 may be a silicon nitride layer or silicon oxynitride layer.

Step 2023: a first active layer and a second active layer are formed on the gate electrode insulating layer.

In the embodiment of the present disclosure, the first active layer and the second active layer are disposed on the same layer. Forming the first active layer and the second active layer in step 2023 may comprise: forming a first semiconductor layer, and forming a first active layer by a patterning process; and forming a second semiconductor layer, and forming a second active layer by a patterning process. The first active layer and the second active layer are located in the regions of two pixel units of adjacent rows corresponding to the pixel unit groups on the gate electrode insulating layer. In the process of forming the first active layer and the second layer, the first semiconductor layer and the second semiconductor layer may be processed separately by the patterning process twice to form the first active layer and the second active layer, and may also be processed simultaneously by a single patterning process to form the first active layer and the second active layer.

In the embodiment of the present disclosure, forming the first semiconductor layer and forming the first active layer by the patterning process comprises: forming a doped amorphous silicon layer; forming a heavily doped amorphous silicon layer; and processing the doped amorphous silicon layer and the heavily doped amorphous silicon layer by the patterning process to form the first active layer. Forming the second semiconductor layer and forming the second active layer by the patterning process comprises: forming a doped amorphous silicon layer; forming a heavily doped amorphous silicon layer; and processing the doped amorphous silicon layer and the heavily doped amorphous silicon layer by the patterning process to form the second active layer. In the process of forming the first active layer and the second active layer, the doped amorphous silicon and the heavily doped amorphous silicon may be processed by a single patterning process to obtain the first active layer or the second active layer, or the doped amorphous silicon and the heavily doped amorphous silicon may be processed by the patterning process twice or multiple times to obtain the first active layer or the second active layer.

There are two manners to form the doped amorphous silicon layer or the heavily doped amorphous silicon layer. One manner is to deposit an undoped amorphous silicon layer first, and then dope the undoped amorphous silicon layer to obtain the doped amorphous silicon layer or the heavily doped amorphous silicon layer. The other manner is to directly deposit the doped amorphous silicon or the heavily doped amorphous silicon layer. The above depositing manner comprises but is not limited to plasma enhanced chemical vapor deposition (PECVD) method.

In the embodiment of the present disclosure, the first semiconductor and the second semiconductor layer are formed in sequence, or the first semiconductor layer and the second semiconductor layer are formed alternately.

The first semiconductor layer and the second semiconductor layer being formed in sequence refers to that the first semiconductor layer is formed first, and then the second semiconductor layer is formed, or the second semiconductor layer is formed first and then the first semiconductor layer is formed, which may be made reference to the implementation I and implementation II of the first manner, and the implementation I and implementation II of the second manner. The first semiconductor layer and the second semiconductor layer being formed alternately refers to that one part of the first semiconductor layer is formed first, then one part of the second semiconductor layer is formed, then the other part of the first semiconductor layer is formed, and then the other part of the second semiconductor layer is formed (or the other part of the second semiconductor layer is formed and then the other part of the first semiconductor layer is formed). Or, one part of the second semiconductor layer is formed first, then one part of the first semiconductor layer is formed, then the other part of the first semiconductor layer is formed, and then the other part of the second semiconductor layer is formed (or the other part of the second semiconductor layer is formed and then the other part of the first semiconductor layer is formed), which may be made reference to implementation III of the first manner and the implementation III of the second manner. One part of the first semiconductor layer and one part of the second semiconductor layer are doped amorphous silicon layer or doped amorphous silicon film. The other parts of the first semiconductor layer and one part of the second semiconductor layer are heavily doped amorphous silicon layer or heavily doped amorphous silicon film.

In the embodiment of the present disclosure, the specific process of forming the first active layer and the second active layer on the gate electrode insulating layer comprises the following implementing manners:

First manner: the n a-Si layer, the n+ a-Si layer, the p a-Si layer and the p+ a-Si layer are formed. The n a-Si layer, the n+ a-Si layer, the p a-Si layer and the p+ a-Si layer are processed by a patterning process to obtain the first active layer and the second active layer.

Exemplarily, the first active layer and the second active layer are two active layers corresponding to the two pixel units of adjacent columns in the pixel unit group. The first active layer adopts N-type doping, and the second active layer adopts P-type doping.

The above n a-Si layer covers the whole pixel region (the region of the pixel units) where the first active layer is, and the n+ a-Si layer covers the n a-Si layer. The p a-Si layer covers the whole pixel region where the second active layer is, and the P+ a-Si layer covers the p a-Si layer. Further, the n a-Si layer and the p a-Si layer may further cover parts of a region between two pixel regions respectively, such that the n a-Si layer and the p a-Si layer cover the whole gate electrode insulating layer.

There are many implementations to form the n a-Si layer, the n+ a-Si layer, the p a-Si layer and the p+ a-Si layer.

Implementation I: a layer of n a-Si film is manufactured on the gate electrode insulating layer. The n a-Si film is processed through the patterning process to form the n a-Si layer. A layer of n+ a-Si film is manufactured on the gate electrode insulating layer with the n a-Si layer. The n+ a-Si film is processed by the patterning process to form the n+ a-Si layer. A layer of p a-Si film is manufactured on the gate electrode insulating layer with the n a-Si layer and the n+ a-Si layer. The p a-Si film is processed by the patterning process to form the p a-Si layer. A layer of p+ a-Si film is manufactured on the gate electrode insulating layer with the p a-Si layer. The p+ a-Si film is processed by the patterning process to form the p+ a-Si layer. In implementation I, the p a-Si layer and the p+ a-Si layer may also be manufactured first, and then the n a-Si layer and the n+ a-Si layer are manufactured.

Implementation II: a layer of n a-Si film is manufactured on the gate electrode insulating layer. A layer of n+ a-Si film is manufactured on the n a-Si film. The n a-Si film and the n+ a-Si film are processed by the patterning process to form the n a-Si layer and the n+ a-Si layer. A layer of p a-Si film is manufactured on the gate electrode insulating layer with the n a-Si layer and the n+ a-Si layer. A layer of p+ a-Si film is manufactured on the p a-Si film. The p a-Si film and the p+ a-Si film are processed by the patterning process to form the p a-Si layer and the p+ a-Si layer. In implementation II, the p a-Si layer and the p+ a-Si layer may be manufactured first, and then the n a-Si layer and the n+ a-Si layer are manufactured.

Implementation III: a layer of n a-Si film is manufactured on the gate electrode insulating layer. The n a-Si film is processed by the patterning process to form the n a-Si layer. A layer of p a-Si film is manufactured on the gate electrode insulating layer with the n a-Si layer. The p a-Si film is processed by the patterning process to form the p a-Si layer. A layer of n+ a-Si film is manufactured on the gate electrode insulating layer with the n a-Si layer and the p a-Si layer. The n+ a-Si film is processed by the patterning process to form the n+ a-Si layer. A layer of p+ a-Si film is manufactured on the gate electrode insulating layer with the n+ a-Si layer. The p+ a-Si film is processed by the patterning process to form the p+ a-Si layer. In implementation III, the p a-Si layer may also be manufactured first, and then the n a-Si layer is manufactured. After the n a-Si layer and the p a-Si layer are manufactured, the p+ a-Si layer may be manufactured, and then the n+ a-Si layer is manufactured.

Compared with other implementations, the patterning process is performed less in implementation II and the manufacturing is more convenient. However, since the thickness of the film layer processed by the single patterning process is big, the requirement on the patterning process is high.

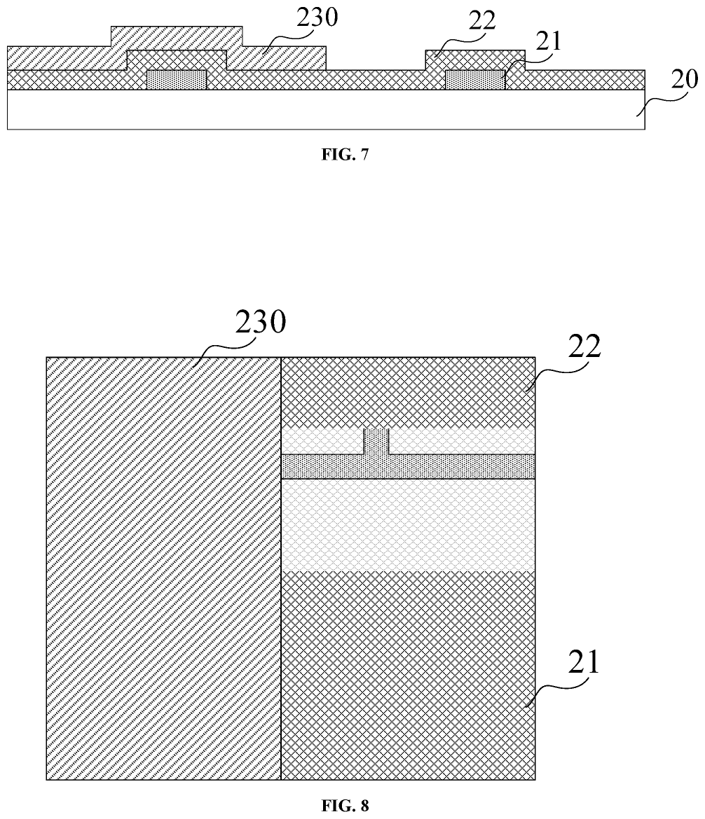

Implementation I in the first manner will be described in detail with reference to FIG. 7 to FIG. 16.

FIG. 7 and FIG. 8 are structural schematic diagrams of an array substrate after an n a-Si layer is formed during the process of manufacturing the array substrate. Referring to FIG. 7 and FIG. 8, a layer of n a-Si film is manufactured on the gate electrode insulating layer 22 and the n a-Si film is processed by a patterning process to form an n a-Si layer 230.

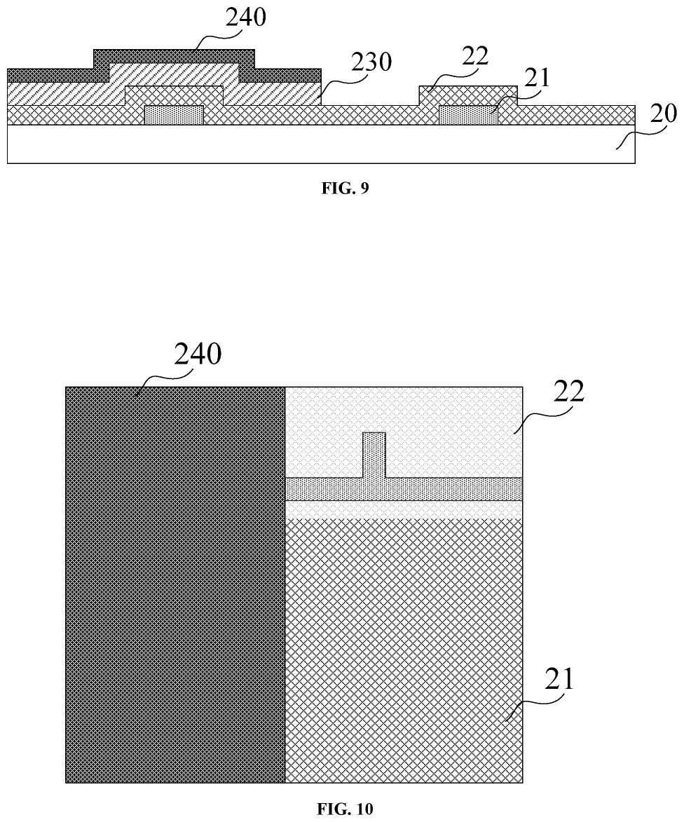

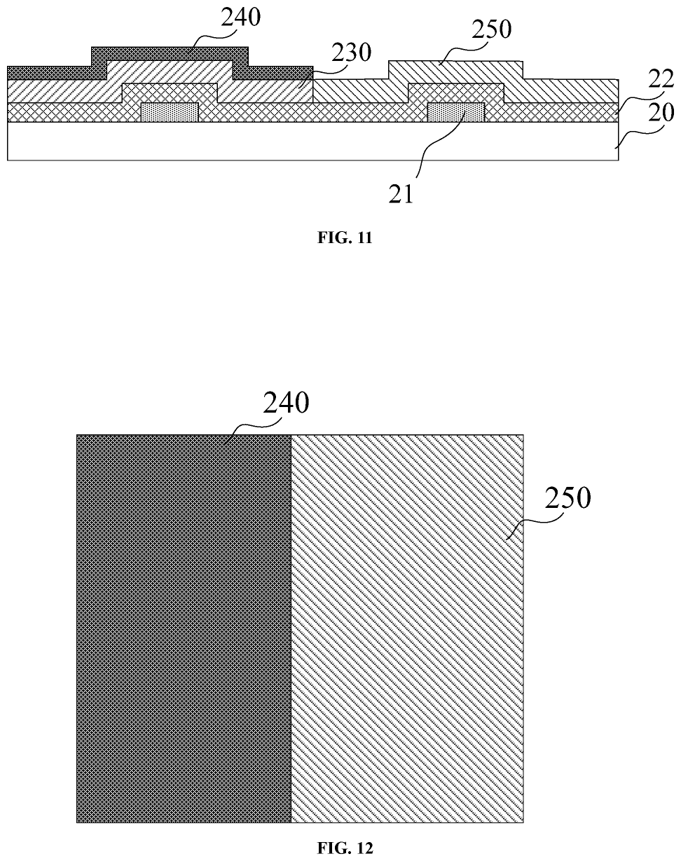

FIG. 9 and FIG. 10 are structural schematic diagrams of an array substrate after an n+ a-Si layer is formed during the process of manufacturing the array substrate. Referring to FIG. 9 and FIG. 10, a layer of n+ a-Si film is manufactured and then the n+ a-Si thin film is processed by a patterning process to form an n+ a-Si layer 240. The n+ a-Si layer 240 is formed on the n a-Si layer 230.

FIG. 11 and FIG. 12 are structural schematic diagrams of an array substrate after a p a-Si layer is formed during the process of manufacturing the array substrate. Referring to FIG. 11 and FIG. 12, a layer of p a-Si film is manufactured and then the p a-Si film is processed by a patterning process to form a p a-Si layer 250. The p a-Si layer 250 and the n a-Si layer 230 covers the whole gate electrode insulating layer 22.

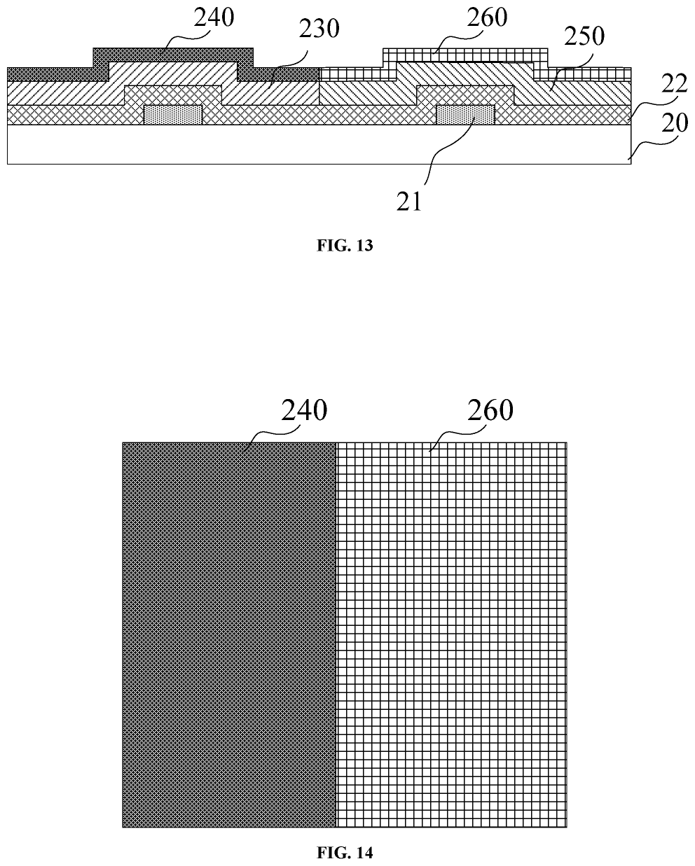

FIG. 13 and FIG. 14 are structural schematic diagrams of an array substrate after a p+ a-Si layer is formed during the process of manufacturing the array substrate. Referring to FIG. 13 and FIG. 14, a layer of p+ a-Si film is manufactured and then the p+ a-Si film is processed by a patterning process to form a p+ a-Si layer 260. The p+ a-Si layer 260 is formed on the p a-Si layer 250.

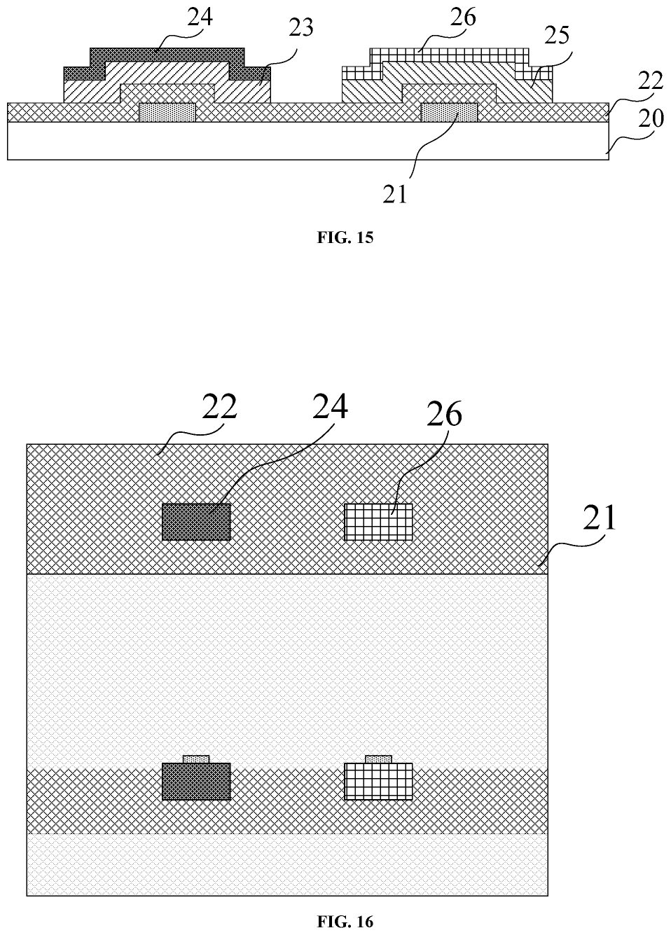

FIG. 15 and FIG. 16 are structural schematic diagrams of an array substrate after a first active layer and a second active layer are formed during the process of manufacturing the array substrate. Referring to FIG. 15 and FIG. 16, after the n a-Si layer 230, the n+ a-Si layer 240, the p a-Si layer 250 and p+ a-Si layer 260 are formed, the n a-Si layer 230, the n+ a-Si layer 240, the p a-Si layer 250 and p+ a-Si layer 260 are processed through a pattering process to obtain parts numbered 23, 24, 25 and 26 respectively in the figures and form the first active layer and the second active layer. The first active layer consists of part 23 and part 24, and the second active layer consists of part 25 and part 26.

The manufacturing processes in the other implementations in the first manner are similar to the one in the above implementation and are not repeated herein.

The second manner: an n a-Si film, an n+ a-Si film, a p a-Si film and a p+ a-Si film are formed. During the process of forming each film, the film is directly processed by a patterning process to form the first active layer and the second active layer. All of the a-Si film, the n+ a-Si film, the p a-Si film and the p+ a-Si film covers the whole gate electrode insulating layer.

The second manner includes the following specific implementations:

Implementation I: an n a-Si film and an n+ a-Si film are sequentially formed on the gate electrode insulating layer. The n a-Si film and the n+ a-Si film are processed by a patterning process to obtain the first active layer. A p a-Si film and a p+a-Si film are sequentially formed on the gate electrode insulating layer. The p a-Si film and the p+ a-Si film are processed by a patterning process to obtain the second active layer. In implementation I, the second active layer may be manufactured first and then the first active layer may be manufactured.

Implementation II: an n a-Si film is manufactured on the gate electrode insulating layer and is processed by a patterning process to obtain a first layer of the first active layer. An n+ a-Si film is manufactured on the gate electrode insulating layer and is processed by a patterning process to obtain a second layer of the first active layer. A p a-Si film is manufactured on the gate electrode insulating layer and is processed by a patterning process to obtain a first layer of the second active layer. A p+ a-Si film is manufactured on the gate electrode insulating layer and is processed by a patterning process to obtain a second layer of the second active layer. In implementation II, the second active layer may be manufactured first and then the first active layer may be manufactured.

Implementation III: an n a-Si film is manufactured on the gate electrode insulating layer and is processed by a patterning process to obtain a first layer of the first active layer. A p a-Si film is manufactured on the gate electrode insulating layer and is processed by a patterning process to obtain a first layer of the second active layer. An n+ a-Si film is manufactured on the gate electrode insulating layer and is processed by a patterning process to obtain a second layer of the first active layer. A p+ a-Si film is manufactured on the gate electrode insulating layer and is processed by a patterning process to obtain a second layer of the second active layer. In implementation III, the first layer of the second active layer may be manufactured first and then the first layer of the first active layer may be manufactured. After the first layer of the first active layer and the first layer of the second active layer are manufactured, the second layer of the second active layer may be manufactured and then the second layer of the first active layer may be manufactured.

In step 2024, a source-drain electrode layer pattern is formed on the first active layer and the second active layer. The source-drain electrode layer pattern includes a plurality of data lines and a plurality of source-drain electrodes.

Exemplarily, step 2024 may comprise: forming a second conductive layer on the first active layer and the second active layer, and processing the second conductive layer by the patterning process to form the source-drain electrode layer pattern, wherein the plurality of source-drain electrodes are a plurality of source electrodes and a plurality of drain electrodes, and a source electrode and a drain electrode are formed in each pixel region.

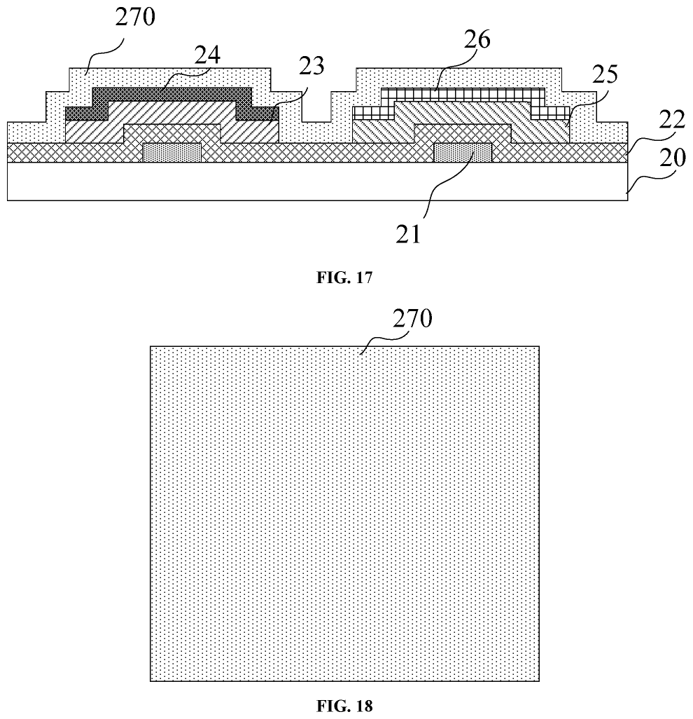

FIGS. 17 and 18 show structural schematic diagrams of an array substrate after the second conductive layer is formed in the manufacturing process. Referring to FIGS. 17 and 18, after the first active layer and the second active layer are formed, the second conductive layer 270 is formed.

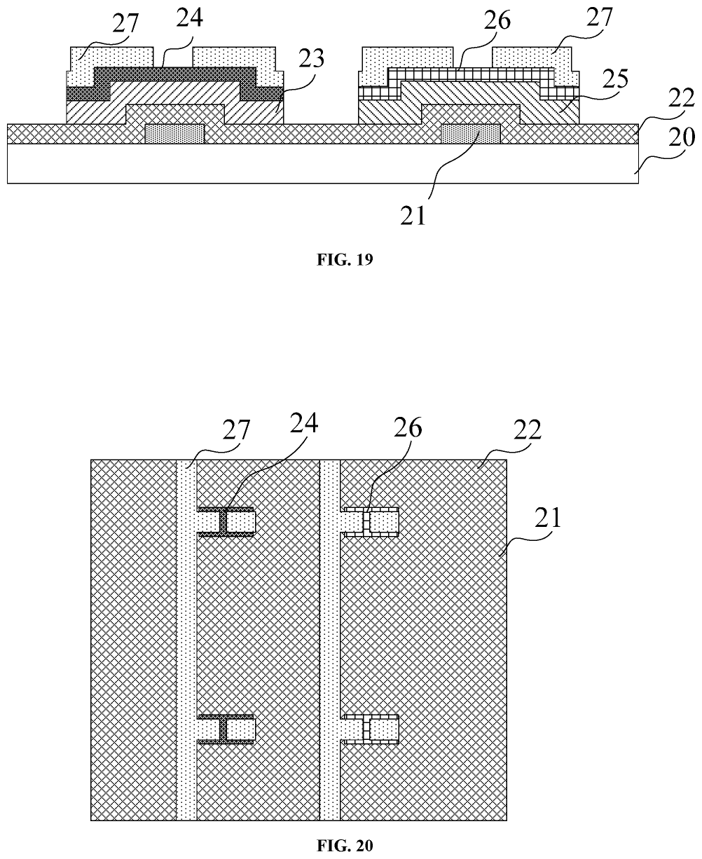

FIGS. 19 and 20 show structural schematic diagrams of an array substrate after the source-drain electrode layer pattern is formed in the manufacturing process. Referring to FIGS. 19 and 20, the second conductive layer 270 is processed by a patterning process to obtain a source-drain electrode layer pattern 27.

In the embodiment of the present disclosure, the second conductive layer may be a metal layer, made of, for example Al, Cu, Mo, Cr, Ti, etc., or an alloy of the above metal. The second conductive layer may be made in a manner of sputtering, etc.

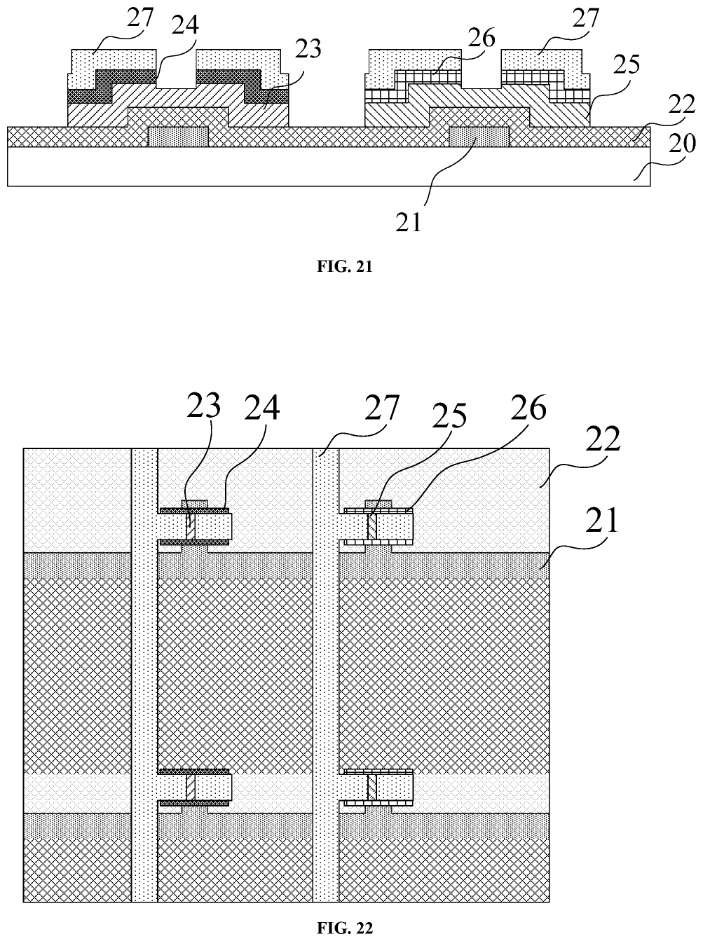

After the source electrode and the drain electrode are formed, the parts between the source electrode and the drain electrode in the p+ a-Si layer and the n+ a-Si layer are removed by the patterning process. As shown in FIGS. 21 and 22, the parts between the source electrode and the drain electrode in the p+ a-Si layer (the p+ a-Si layer applied with the patterning process and corresponding to number 26 in the figure) and the n+ a-Si layer (the n+ a-Si layer applied with the patterning process and corresponding to number 24 in the figure) are removed by the patterning process, and part of the p a-Si layer (the p a-Si layer applied with the patterning process and corresponding to number 25 in the figure) and part of the n a-Si layer (the n a-Si layer applied with the patterning process and corresponding to number 23 in the figure) are exposed.

Further, step 202 may further comprise step 2025, in which an insulating layer is formed on the substrate.

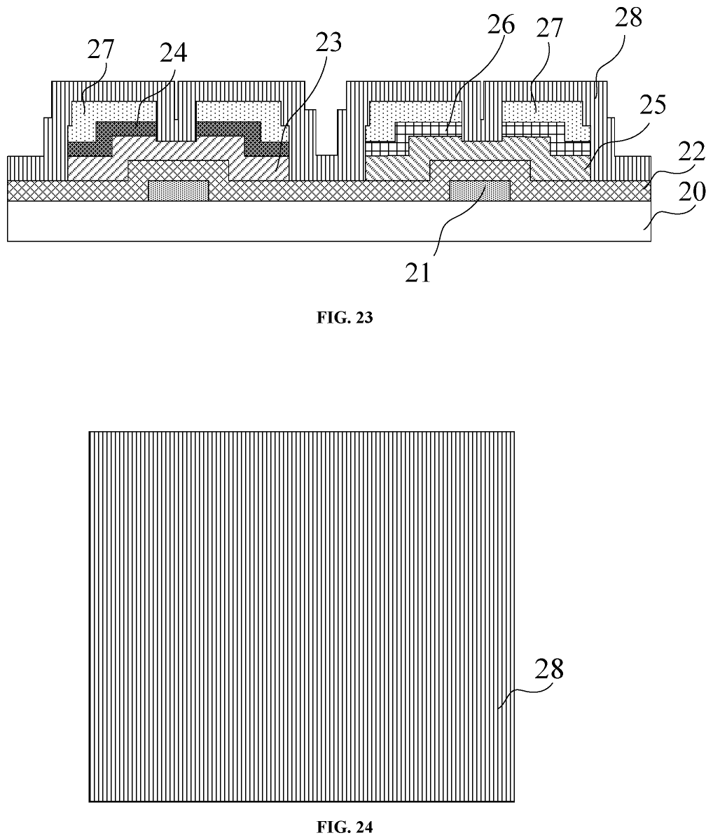

FIGS. 23 and 24 show structural schematic diagrams of an array substrate after the insulating layer is formed in the manufacturing process of the array substrate. Referring to FIGS. 23 and 24, an insulating layer 28 is formed on the substrate (a depositing manner may be adopted). The insulating layer 28 may be a silicon nitride or silicon oxynitride layer. The insulating layer 28 covers the substrate 20. The insulating layer is disposed to play a role of protecting the substrate.

In the embodiment of the present disclosure, the above patterning process may be implemented by an etching process. The etching process may be dry etching or wet drying implemented using photoresist as a mask for shielding.

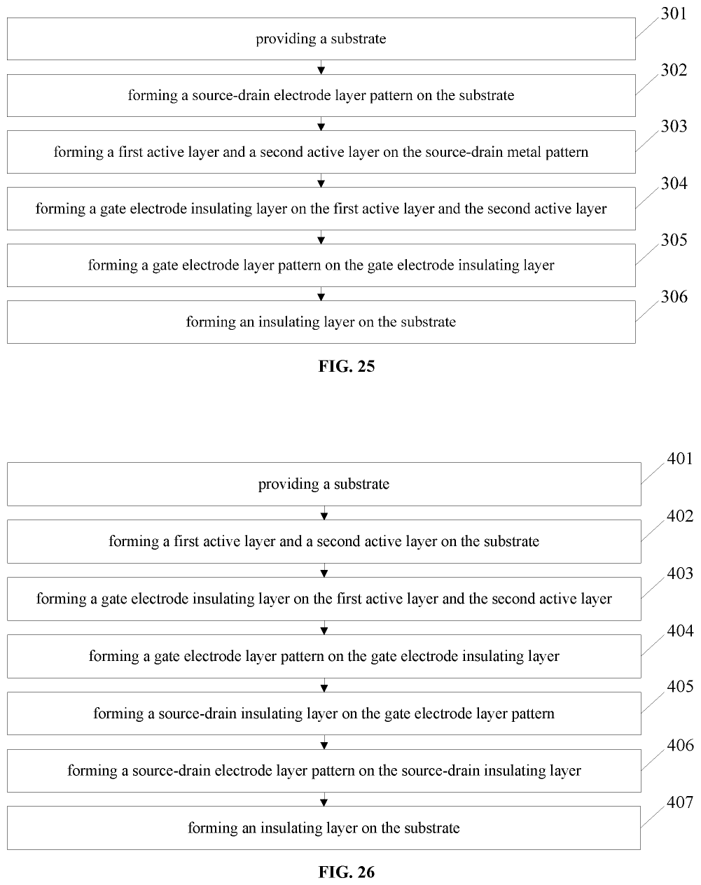

FIG. 25 is a flow chart of a method for manufacturing another array substrate provided in an embodiment of the present disclosure. The method may be used to manufacture the array substrate in FIG. 1. The TFT in the array substrate manufactured with the method shown in FIG. 25 is a top gate TFT. Referring to FIG. 25, the method includes the following steps.

In step 301: a substrate is provided.

Step 301 is the same as step 201 and is not repeated herein.

In step 302, a source-drain electrode layer pattern is formed on the substrate. The source-drain electrode layer pattern includes a plurality of data lines and a plurality of source-drain electrodes.

The implementation detail for step 302 is the same as that for step 2024 and is not repeated herein.

In step 303, a first active layer and a second active layer are formed on the source-drain metal pattern.

The implementation detail for step 303 is the same as that for step 2023 and is not repeated herein.

The difference between the implementation detail for step 303 and the implementation detail for step 3023 is that the manners for forming the first active layer and the second active layer are different.

In the embodiment of the present disclosure, forming the first semiconductor layer and forming the first active layer by a patterning process comprises: forming a heavily doped amorphous silicon layer; forming a doped amorphous silicon layer; and processing the heavily doped amorphous silicon layer and the doped amorphous silicon layer by a patterning process to form the first active layer. Forming the second semiconductor layer and forming the second active layer by a patterning process comprises: forming a heavily doped amorphous silicon layer; forming a doped amorphous silicon layer; and processing the heavily doped amorphous silicon layer and the doped amorphous silicon layer by a patterning process to form the second active layer.

In step 304, a gate electrode insulating layer is formed on the first active layer and the second active layer.

The implementation detail for step 304 is the same as that for step 2022 and is not repeated herein.

In step 305, a gate electrode layer pattern is formed on the gate electrode insulating layer. The gate electrode layer pattern includes a plurality of gate lines and a plurality of gate electrodes.

The implementation detail for step 305 is the same as that for step 2021 and is not repeated herein.

Further, the method may further include step 306, in which an insulating layer is formed on the substrate.

Gate lines, data lines, active layers and source-drain electrodes are formed through steps 302-306 to form a plurality of first TFTs and a plurality of second TFTs. The first TFTs and the second TFTs are top gate TFTs.

FIG. 26 is a flow chart of a method for manufacturing another array substrate provided in an embodiment of the present disclosure. The method may be used to manufacture the array substrate in FIG. 1. The TFT in the array substrate manufactured with the method shown in FIG. 26 is a top gate TFT. Referring to FIG. 26, the method includes the following steps.

In step 401: a substrate is provided.

Step 401 is the same as step 201 and is not repeated herein.

In step 402, a first active layer and a second active layer are formed on the substrate.

The implementation detail for step 402 is the same as that for step 2023 and is not repeated herein.

In step 403, a gate electrode insulating layer is formed on the first active layer and the second active layer.

The implementation detail for step 403 is the same as that for step 2022 and is not repeated herein.

In step 404, a gate electrode layer pattern is formed on the gate electrode insulating layer. The gate electrode layer pattern includes a plurality of gate lines and a plurality of gate electrodes.

The implementation detail for step 404 is the same as that for step 2021 and is not repeated herein.

In step 405, a source-drain insulating layer is formed on the gate electrode layer pattern.

The method for manufacturing the source-drain insulating layer may be the same as that for manufacturing the gate electrode insulating layer. That is, the implementation detail for step 405 may be the same as that for step 2022 and is not repeated herein.

In step 406, a source-drain electrode layer pattern is formed on the source-drain insulating layer. The source-drain electrode layer pattern includes a plurality of data lines and a plurality of source-drain electrodes.

The implementation detail for step 406 is the same as that for step 2024 and is not repeated herein.

Further, the method may further include step 407, in which an insulating layer is formed on the substrate.

Gate lines, data lines, active layers and source-drain electrodes are formed through steps 402-407 to form a plurality of first TFTs and a plurality of second TFTs. The first TFTs and the second TFTs are top gate TFTs.

The present disclosure further provides a display panel including the array substrate shown in FIG. 1.

In the present disclosure, in the same row of pixel units, the two pixel units of adjacent columns are connected to one data line. The TFTs of the two pixel units connected to the same data line in the same row are transistors of different types. The pixel units of the same row are connected to one gate line. In this way, the TFTs of the two pixel units connected to the same data line in the same row may be controlled to be turned on and off in sequence by outputting different voltage signals through one gate line in a time sharing manner. It is ensured that the data signal is written into the two pixel units connected to two TFTs by one data line in a time sharing manner. That is, the TFTs of one row of pixel units in the original dual gate design may be controlled to be turned on and off using one gate line. There is no need to provide two gate lines for one row of pixel units. Thus, the number of the gate lines is reduced, and the aperture opening ratio of the TFT-LCD increases.

In an implementation of the present disclosure, the display panel further includes a gate driver and a source driver. The date driver is configured to output a gate electrode control signal to each gate line in sequence in the scan direction. The gate electrode control signal includes a first voltage signal and a second voltage signal. The first voltage signal and the second voltage signal are configured to turn on two different types of transistors. The source driver is configured to output a first data signal to the data lines when the gate driver outputs the first voltage signal to any gate line and output a second data signal to the data lines when the gate driver outputs the second voltage signal to any gate line.

The first voltage signal is a positive voltage signal and the second voltage is a negative voltage signal. During operation, the gate driver outputs a positive voltage and a negative voltage signal to one gate line and then outputs a positive voltage and a negative voltage signal to a next gate line.

The first data signal and the second data signal comprise a plurality of sub-signals output to a plurality of data lines. Each sub-signal is configured to drive the pixel units on one data line. The plurality of sub-signals may be the same or different. The first data signal corresponds to a display picture of the pixel units having the transistors of one type (for example, N-type transistors). The second data signal corresponds to a display picture of the pixel units having the transistors of the other type (for example, P-type transistors).

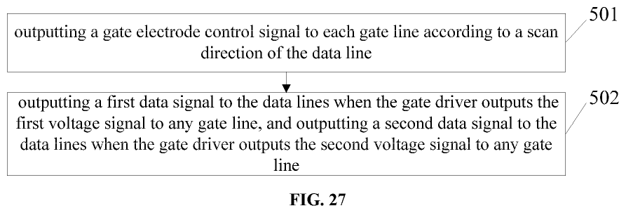

FIG. 27 is a flow chart of a method for driving a display panel provided in an embodiment of the present disclosure. This method may be used to drive the above-mentioned display panel. Referring to FIG. 27, the method includes the following steps.

In step 501, a gate electrode control signal is output to each gate line according to a scan direction of the data line, wherein the gate electrode control signal comprises a first voltage signal and a second voltage signal, and the first voltage signal and the second voltage signal are configured to turn on transistors of two different types. The scan direction of the data line is the same as the length direction of the data line.

The first voltage signal may be a positive voltage signal and the second voltage may be a negative voltage signal. A positive voltage and a negative voltage signal are output to one gate line and then a positive voltage and a negative voltage signal are output to a next gate line.

In step 502, a first data signal is output to the plurality of data lines when the gate driver outputs the first voltage signal to any gate line, and a second data signal is output to the plurality of data lines when the gate driver outputs the second voltage signal to any gate line.

The first data signal and the second data signal comprise a plurality of sub-signals output to a plurality of data lines. Each sub-signal is configured to drive the pixel units on one data line. The plurality of sub-signals may be the same or different. The first data signal corresponds to a display picture of the pixel units having the transistors of one type (for example, N-type transistors). The second data signal corresponds to a display picture of the pixel units having the transistors of the other type (for example, P-type transistors). Outputting the first data signal or the second data signal to the plurality of data lines means to output the first data signal or the second data signal to all data lines simultaneously, and each data line corresponds to one sub-signal in the first data signal or the second data signal.

When the gate line outputs a positive voltage signal, the N-type transistor is turned on, and the P-type transistor is turned off. When a negative voltage signal is output, the P-type transistor is turned on, and the N-type transistor is turned off. The gate line outputs the positive voltage signal first and then outputs the negative voltage signal or outputs the negative voltage signal first and then outputs the positive voltage signal within the scan time of one row of pixel units.

In the embodiments of the present disclosure, the time duration of the positive voltage signals and the negative voltage signals in the gate electrode control signals may be equal.

The present disclosure further provides a display device, including the above-mentioned display panel. In practice, the display device may be a mobile phone, a tablet computer, a television, a display, a laptop computer, a digital photo frame, a navigator or any other product or part with a display function.

The foregoing are only some embodiments of the present disclosure, and are not intended to limit the present disclosure. Within the spirit and principles of the disclosure, any modifications, equivalent substitutions, improvements, etc., are within the scope of protection of the present disclosure.

1. An array substrate, comprising:
a plurality of gate lines, a plurality of data lines, and a plurality of pixel units defined by the gate lines and the data lines in cross arrangement, wherein the plurality of pixel units are arranged in an array;
each row of pixel units is connected to one corresponding gate line; each row of pixel units comprises a plurality of pixel unit groups; each pixel unit group comprises two pixel units of adjacent columns; the two pixel units of adjacent columns are connected to one data line; and thin film transistors of the two pixel units in the pixel unit group are transistors of different types.

2. The array substrate according to claim 1, wherein in the thin film transistors of two pixel units in the pixel unit group, one thin film transistor is an N-type transistor, and the other thin film transistor is a P-type transistor.

3. The array substrate according to claim 2, wherein the N-type transistor comprises a gate electrode, a gate electrode insulating layer, a first active layer, a source-drain electrode and an insulating layer laminated in sequence; and the P-type transistor comprises a gate electrode, a gate electrode insulating layer, a second active layer, a source-drain electrode and an insulating layer laminated in sequence.

4. The array substrate according to claim 2, wherein the N-type transistor comprises a source-drain electrode, a first active layer, a gate electrode insulating layer, a gate electrode, and an insulating layer laminated in sequence; and the P-type transistor comprises a source-drain electrode, a second active layer, a gate electrode insulating layer, a gate electrode, and an insulating layer laminated in sequence.

5. The array substrate according to claim 2, wherein the N-type transistor comprises a first active layer, a gate electrode insulating layer, a gate electrode, a source-drain electrode insulating layer, a source-drain electrode, and an insulating layer laminated in sequence; and the P-type transistor comprises a second active layer, a gate electrode insulating layer, a gate electrode, a source-drain electrode insulating layer, a source-drain electrode, and an insulating layer laminated in sequence.

6. The array substrate according to claim 3, wherein the first active layer comprises an N-doped amorphous silicon layer and a heavily N-doped amorphous silicon layer; and the second active layer comprises a P-doped amorphous silicon layer and a heavily P-doped amorphous silicon layer.

7. A manufacturing method for an array substrate, comprising:
forming gate lines, data lines, active layers and source-drain electrodes on a substrate, so as to form a plurality of first thin film transistors and a plurality of second thin film transistors; wherein
the active layers comprise a first active layer and a second active layer, the first active layer is an active layer of the first thin film transistors, and the second active layer is the active layer of the second thin film transistors;
a plurality of pixel units is defined by the gate lines and the data lines in cross arrangement; the plurality of pixel units are arranged in an array; each pixel unit comprises a thin film transistor; each row of pixel units is connected to one corresponding gate line; each row of pixel units comprises a plurality of pixel unit groups; each pixel unit group comprises two pixel units of adjacent columns; the two pixel units of adjacent columns are connected to one data line; and
the first thin film transistors and the second thin film transistor are two thin film transistors corresponding to the two pixel units of adjacent columns in the pixel unit group; and the first thin film transistor and the second thin film transistor are transistors of different types.

8. The manufacturing method according to claim 7, wherein forming gate lines, data lines, active layers and source-drain electrodes on a substrate comprises:
forming a gate electrode layer pattern on the substrate, the gate electrode layer pattern comprising a plurality of gate lines and a plurality of gate electrodes;
forming a gate electrode insulating layer on the gate electrode layer pattern;
forming a first active layer and a second active layer on the gate electrode insulating layer; and
forming a source-drain electrode layer pattern on the first active layer and the second active layer, the source-drain electrode layer pattern comprising a plurality of data lines and a plurality of source-drain electrodes.

9. The manufacturing method according to claim 7, wherein forming gate lines, data lines, active layers and source-drain electrodes on a substrate comprises:
forming a source-drain electrode layer pattern on the substrate, the source-drain electrode layer pattern comprising a plurality of data lines and a plurality of source-drain electrodes.
forming a first active layer and a second active layer on the source-drain electrode layer pattern;
forming a gate electrode insulating layer on the first active layer and the second active layer; and
forming a gate electrode layer pattern on the gate electrode insulating layer, the gate electrode layer pattern comprising a plurality of gate lines and a plurality of gate electrodes.

10. The manufacturing method according to claim 7, wherein forming gate lines, data lines, active layers and source-drain electrodes on a substrate comprises:
forming a first active layer and a second active layer on the substrate;
forming a gate electrode insulating layer on the first active layer and the second active layer;
forming a gate electrode layer pattern on the gate electrode insulating layer, the gate electrode layer pattern comprising a plurality of gate lines and a plurality of gate electrodes;
forming a source-drain electrode insulating layer on the gate electrode layer pattern; and
forming a source-drain electrode layer pattern on the source-drain electrode insulating layer, the source-drain electrode pattern comprising a plurality of data lines and a plurality of source-drain electrodes.

11. The manufacturing method according to claim 8, wherein forming a first active layer and a second active layer comprises:
forming a first semiconductor layer, and forming the first active layer by a patterning process; and
forming a second semiconductor layer, and forming the second active layer by a patterning process;
wherein the first active layer and the second active layer are located in regions of two pixel units of adjacent columns corresponding to the pixel unit group on the gate electrode insulating layer, respectively.

12. The manufacturing method according to claim 11, wherein
forming a first semiconductor layer, and forming the first active layer by a patterning process comprises:
forming a doped amorphous silicon layer; forming a heavily doped amorphous silicon layer; and processing the doped amorphous silicon layer and the heavily doped amorphous silicon layer by the patterning process to form the first active layer; and
forming a second semiconductor layer, and forming the second active layer by a patterning process comprises:
forming a doped amorphous silicon layer; forming a heavily doped amorphous silicon layer; processing the doped amorphous silicon layer and the heavily doped amorphous silicon layer by the patterning process to form the second active layer.

13. The manufacturing method according to claim 11, wherein
forming a first semiconductor layer, and forming the first active layer by a patterning process comprises:
forming a heavily doped amorphous silicon layer; forming a doped amorphous silicon layer; and processing the heavily doped amorphous silicon layer and the doped amorphous silicon layer by the patterning process to form the first active layer; and
forming a second semiconductor layer, and forming the second active layer by a patterning process comprises:
forming a heavily doped amorphous silicon layer; forming a doped amorphous silicon layer; and processing the heavily doped amorphous silicon layer and the doped amorphous silicon layer by the patterning process to form the second active layer.

14. The manufacturing method according to claim 12, wherein the first semiconductor layer and the second semiconductor layer are formed in sequence, or the first semiconductor layer and the second semiconductor layer are formed alternately.

15. The manufacturing method according to claim 12, wherein forming a doped amorphous silicon layer comprises:
depositing an undoped amorphous silicon layer, doping the undoped amorphous silicon layer to obtain the doped amorphous silicon layer; or directly depositing a doped amorphous silicon layer.

16. The manufacturing method according to claim 12, wherein forming a heavily doped amorphous silicon layer comprises:
depositing an undoped amorphous silicon layer, and doping the undoped amorphous silicon layer to obtain the heavily doped amorphous silicon layer; or directly depositing a heavily doped amorphous silicon layer.

17. A display panel, comprising the array substrate according to claim 1.

18. A display device, comprising the display panel according to claim 17.

19. A driving method for a display panel, wherein the display panel comprises an array substrate, the array substrate comprises: a plurality of gate lines, a plurality of data lines, and a plurality of pixel units defined by the gate lines and the data lines in cross arrangement, wherein the plurality of pixel units are arranged in an array; each row of pixel units is connected to one corresponding gate line, each row of pixel units comprises a plurality of pixel unit groups, each pixel unit group comprises two pixel units of adjacent columns, the two pixel units of adjacent columns are connected to one data line, and thin film transistors of the two pixel units in the pixel unit group are transistors of different types, and the method comprises:
outputting a gate electrode control signal to each gate line sequentially along a scan direction of the data line, wherein the gate electrode control signal comprises a first voltage signal and a second voltage signal, and the first voltage signal and the second voltage signal are configured to turn on transistors of two different types;
outputting a first data signal to the plurality of data lines when the first voltage signal is output to any gate line, outputting a second data signal to the plurality of data lines when the second voltage signal is output to any gate line, wherein the first data signal and the second data signal both comprise a plurality of sub-signals output to the plurality of data lines, and each sub-signal is configured to drive the pixel unit on one data line.
